(19) United States
(12) Patent Application Publication
(10) Pub. No.: US 2017/0064841 A1
(43) Pub. Date: Mar. 2, 2017

(54) RESIN-COATED COPPER FOIL FOR MANUFACTURING A PRINTED CIRCUIT BOARD AND METHOD OF MANUFACTURING A PRINTED CIRCUIT BOARD USING THE SAME

(71) Applicant: Samsung Electro-Mechanics Co., Ltd., Suwon-si (KR)

(72) Inventor: Youn-gyu HAN, Yongin-si (KR)

(73) Assignee: Samsung Electro-Mechanics Co., Ltd., Suwon-si (KR)

(21) Appl. No.: 15/164,191

(22) Filed: May 25, 2016

(30) Foreign Application Priority Data
Aug. 27, 2015 (KR) 10-2015-0120807

(51) Int. Cl. H05K 3/46; H05K 1/03; H05K 1/02; H05K 3/40; H05K 3/00; H05K 1/09; H05K 3/02

(52) U.S. Cl. CPC H05K 3/4644; H05K 1/09; H05K 1/0373; H05K 3/025; H05K 3/4038; H05K 3/0026; H05K 1/0298; H05K 2201/0141; H05K 2201/0158

(57) ABSTRACT

A resin-coated copper foil includes: a copper foil layer including a first surface and a second surface, wherein a laser absorptance of the first surface of the copper foil layer is greater than a laser absorptance of the second surface of the copper foil layer, and wherein ribs are formed on the second surface of the copper foil layer; a carrier film disposed on the first surface of the copper foil layer; a primer resin layer disposed on the second surface of the copper foil layer; and a build-up resin layer disposed on the primer resin layer.

CROSS REFERENCE TO RELATED APPLICATION(S)

This application claims the benefit under 35 USC 119(a) of Korean Patent Application No. 10-2015-01 20807 filed on Aug. 27, 2015 in the Korean Intellectual Property Office, the entire disclosure of which is incorporated herein by reference for all purposes.

### BACKGROUND

1. Field

The following description relates to a resin-coated copper foil for use in manufacturing a printed circuit board, and a method of manufacturing a printed circuit board using the resin-coated copper foil.

2. Description of Related Art

With the development of lightweight electronic devices having a reduced thickness and size, there is a demand for a printed circuit board having high-density circuit patterns.

A high-density circuit pattern is often formed on an outer-layer circuit of a build-up layer rather than on the core layer on which an inter-layer circuit is formed because the inter-layer circuit is usually formed around ground or power patterns, and also because materials used to form the inter-layer circuit are suitable for a tenting process or a modified semi-additive process.

The tenting process allows forming circuits easily using a subtractive process which eliminates unnecessary parts through an etching process, but it is limited in forming fine-line circuit patterns. A modified semi-additive process using an etched thin Cu foil allows forming circuit patterns with a smaller pitch than that of the tenting process. However, the modified semi-additive process still has technical problems with respect to forming circuit patterns with less than a certain pitch. For example, an embedded pattern process increases adhesion of circuits by embedding fine circuits in an insulating material, but those circuits can be etched during etching of the copper foil, or circuit forming layers are formed asymmetrically, which causes warpage problems.

Fine-line patterns may be formed using a semi-additive process. The semi-additive process forms circuits using a plating process and does not cause a line-width difference between the upper part and lower part of the circuits. However, the semi-additive process includes complicated processes and further requires particular materials. (A prepreg composes a copper clad laminate and is often used as a core material.) Because a prepreg, which used as a core material as well as a build-up material, has a low plating adhesion, the prepreg is not suitable for forming patterns using the semi-additive process. Therefore, a build-up film composed of epoxy resin/thermoplastic resin/silica filler has been used instead of the prepreg for this reason. However, the build-up film has higher curing shrinkage and causes worse warpage problems due to a low rigidity in comparison to the prepreg. There have been attempts to lower a coefficient of thermal expansion and increase rigidity of the build-up film to improve warpage problems. However, since when an excessive amount of a silica filler is used in the build-up film, adhesion between circuits and a resin is deteriorated, curing conditions of materials should be controlled to precipitate the filler in the resin phase. And a resin layer in which less silica is dispersed is then treated to have a surface roughness by etching the resin through a desmear process. However, it is very difficult to develop conditions to achieve uniform roughness. Therefore, the demand for build-up materials which do not require the desmear process has increased.

An example of an adhesive composition for manufacturing a printed circuit board is disclosed in Japanese Patent Publication No. 2006-070176.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a resin-coated copper foil includes: a copper foil layer including a first surface and a second surface, wherein a laser absorptance of the first surface of the copper foil layer is greater than a laser absorptance of the second surface of the copper foil layer, and wherein ribs are formed on the second surface of the copper foil layer; a carrier film disposed on the first surface of the copper foil layer; a primer resin layer disposed on the second surface of the copper foil layer; and a build-up resin layer disposed on the primer resin layer.

The first surface of the copper foil layer may be surface-treated with at least one selected from the group consisting of Ni, Co and Zn.

A thickness of the copper foil layer may be about 0.2 μm to about 3.0 μm.

The primer resin layer may include at least one selected from the group consisting of an epoxy resin, a polyimide resin, a polyamide-imide resin, a polyamide resin, a liquid crystal polymer resin, and a cycloolefin resin.

The primer resin layer may include at least one of a metal oxide filler and an organic filler in an amount greater than 0 wt % and less than about 10 wt %.

The build-up resin layer may include at least one selected from the group consisting of an epoxy resin, a butyral resin, and a polyamide-imide resin.

The build-up resin layer may include at least one of a metal oxide filler and an organic filler in an amount of about 40 wt % to about 80 wt %.

The primer resin layer may have a cure degree of about 90% or above.

The build-up resin layer may be in a B stage.

The primer resin layer may include ribs interfacing with the ribs on the second surface of the copper foil layer.

The ribs on the second surface of the copper foil layer may be uniform in size and shape.

According to another general aspect, a method of manufacturing a printed circuit board includes: preparing a carrier film comprising a release-treated surface; forming a copper foil layer including a first surface and a second surface, wherein the first surface of the copper foil layer faces the release-treated surface of the carrier film, and wherein a laser absorptance of the first surface of the copper foil layer is greater than a laser absorptance of the second surface of the copper foil layer; forming ribs on the second surface of the copper foil layer; forming a primer resin layer on the second surface of the copper foil layer after forming the ribs; forming a build-up resin layer on the primer resin layer to provide a resin-coated copper foil; laminate molding the resin-coated copper foil to face a surface of a center circuit part with the build-up resin layer; exposing a circuit of the center circuit part and a forming via by eliminating the carrier film and irradiating laser light on the first surface of the copper foil layer; and forming a circuit pattern by filling via with a conductive material.

The preparing of the copper foil layer may include surface-treating the first surface of the copper foil layer with at least one selected from the group consisting of Ni, Co, and Zn.

The method may further include eliminating the copper foil layer after the forming of the circuit and the via, and prior to the forming of the circuit pattern.

A thickness of the copper foil layer may be about 0.2 μm to about 3.0 μm.

The forming of the primer resin layer may include forming ribs on the primer resin layer that interface with the ribs on the second surface of the copper foil layer.

The forming of the circuit pattern may include forming the circuit pattern to interface with the ribs on the primer resin layer.

Other features and aspects will be apparent from the following detailed description, the drawings, and the claims.

### BRIEF DESCRIPTION OF THE DRAWINGS

FIG. 1 is a diagram illustrating an example of a resin-coated copper foil for use in manufacturing a printed circuit board.

FIGS. 2A to 2F are diagrams illustrating an example of a method of manufacturing a printed circuit board using the resin-coated copper foil of FIG. 1.

Throughout the drawings and the detailed description, unless otherwise described or provided, the same drawing reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations is described as an example; the sequence of operations is not limited to that set forth herein and may be changed as is known in the art, with the exception of steps and/or operations that necessarily occur in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure is thorough, complete, and conveys the full scope of the disclosure to one of ordinary skill in the art.

In descriptions of components of the disclosure, the same reference numerals are used to designate the same or similar components, regardless of the figure number. Throughout the description of the present disclosure, when describing a certain technology is determined to evade the point of the present disclosure, the pertinent detailed description will be omitted. It will be understood that, although the terms “first,” “second,” “upper,” “lower,” etc. may be used herein to describe various elements, these elements should not be limited by these terms. These terms are only used to distinguish one element from another.

### Resin-Coated Copper Foil

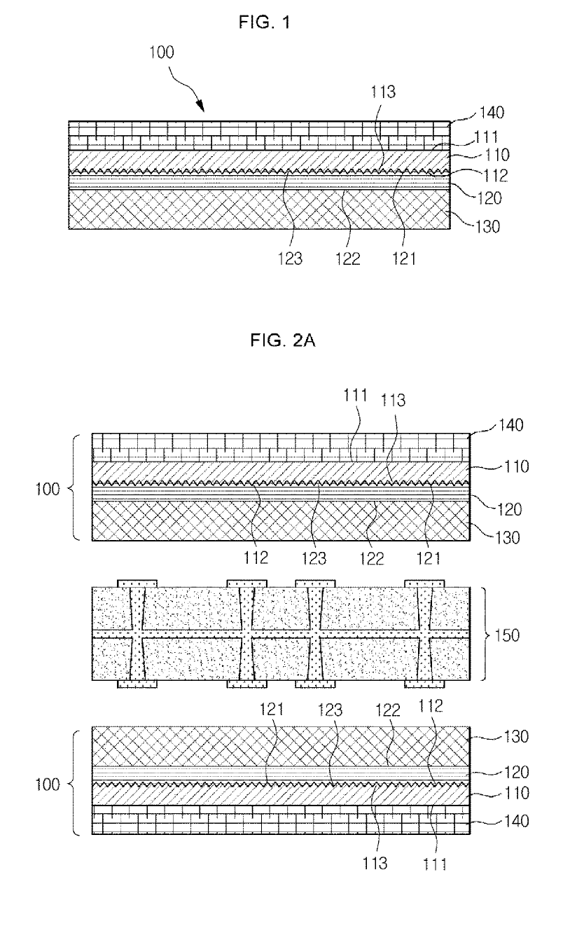

FIG. 1 is a diagram illustrating an example of a resin-coated copper foil (e.g., a laminate) 100 for use in manufacturing a printed circuit board.

Referring to FIG. 1, the resin-coated copper foil 100, according to an example, includes: a copper foil layer 110 having a first, lower surface 111 and a second, lower surface 112; a carrier film 140 formed on the first surface 111 of the copper foil layer 110; a primer resin layer 120 formed on the second surface 112 of the copper foil layer 110; and a build-up resin layer 130 formed on the primer resin layer 120.

The first surface 111 of the copper foil layer 110 may be surface-treated to increase a laser absorptance. The laser absorptance of the first surface 111 of the copper foil layer 110 may be greater than that of the second surface 112.

Because a copper foil generally has a low laser absorptance and a high reflectivity, when a laser is irradiated on the surface of the copper foil, it may not pass through the copper foil. Thus, vias and circuits cannot be formed on the resin that is under the copper foil.

However, when the first surface 111 of the copper foil layer 110 is surface-treated to increase the laser absorptance, via holes can be formed, through a laser process, in the primer resin layer 120 and the build-up resin layer 130 which are formed under the copper foil layer 110.

For example, a surface treatment method of the first surface 111 of the copper foil layer 110 may be a blackening treatment method, a conductive polymer coating treatment method or a metal coating treatment method using a material such as Ni, Co, Zn and the like having a high laser absorptance. However, the surface treatment method is not be limited to the aforementioned methods.

Ribs 113 having uniform roughness are formed on the second surface 112 of the copper foil layer 110. That is, the ribs 113 are uniformly shaped and sized to provide the second surface 112 of the copper foil layer 110 with a uniform roughness. The ribs 113 interface with a first, upper surface 121 of the primer resin layer 120, which is disposed on the second surface 112 of the copper foil layer 110, to transfer the roughness of the ribs 113 to the first surface 121 of the primer resin layer 120. That is, interfacing the ribs 113 with the first surface 121 of the primer resin layer 120 increases adhesion of the first surface 121 of the primer resin layer 120 by forming ribs 123 on the first surface 121 of the primer resin layer 120 that interface with the ribs 113.

A pattern of a circuit or an arrangement of the circuit on a surface of a printed circuit board (“circuit pattern”) formed on a build-up resin is often delaminated due to lack of adhesion between the circuit pattern and the build-up resin layer during a process for manufacturing a printed circuit board. Generally, the adhesion has been improved by controlling curing morphologies of build-up resin layers. However, such controls of curing morphologies are very complicated, cause defects, and increase manufacturing cost.

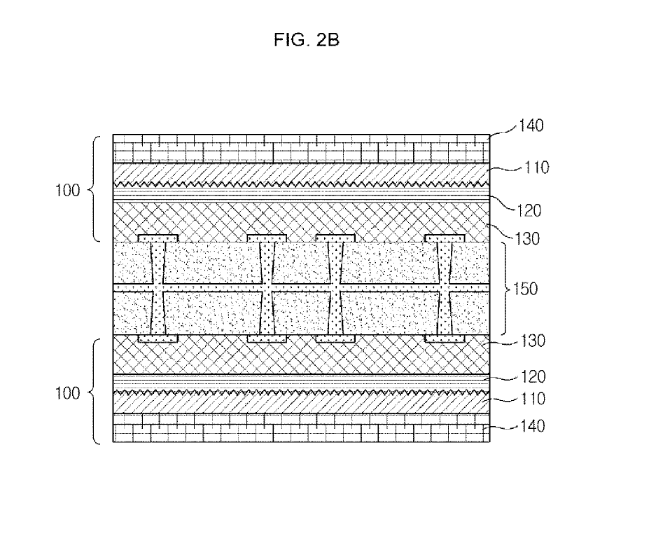

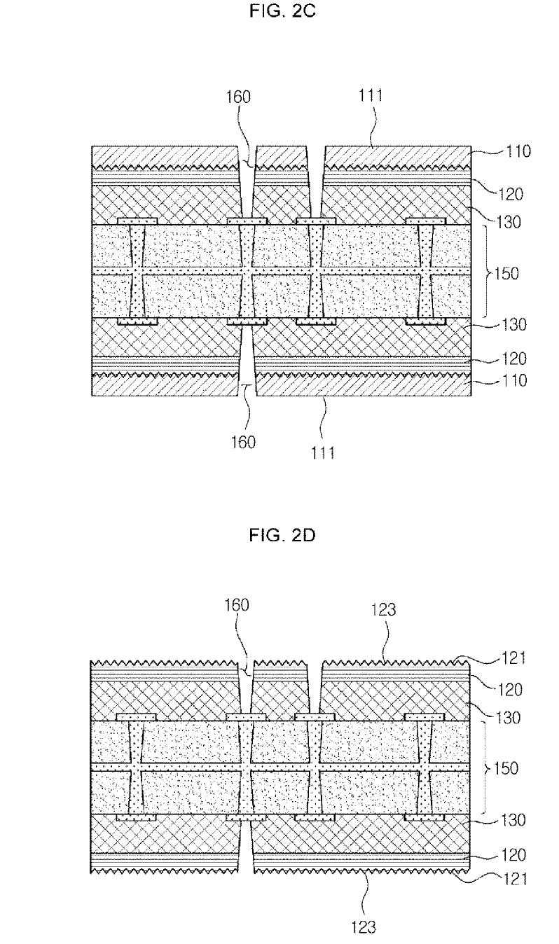

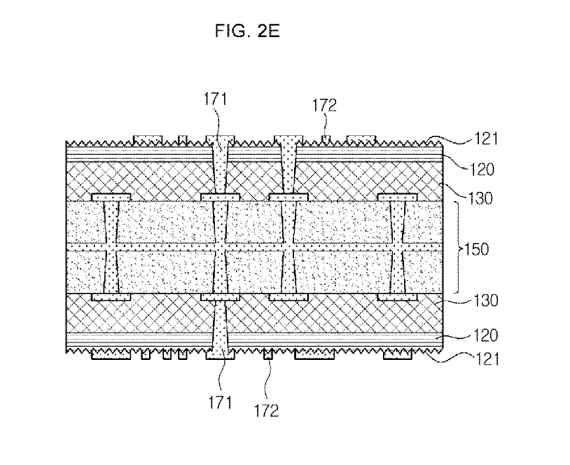

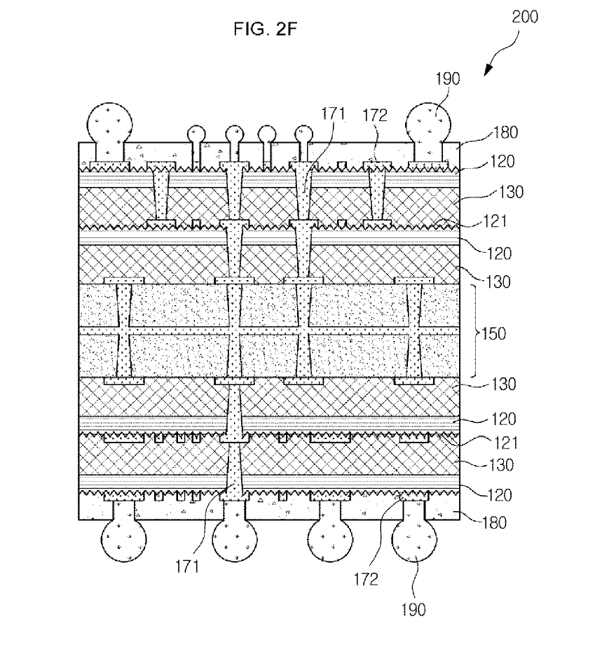

On the other hand, sufficient adhesion between the resin primer layer 120 and the circuit patterns can be provided without any process for controlling curing morphologies when the resin-coated copper foil 100 is prepared by forming the ribs 113 having uniform roughness on the second surface 112 of the copper foil layer 110, forming the primer resin layer 120 on the second surface 112 to transfer the roughness, and forming a circuit pattern 172 (FIGS. 2E and 2F) on the first surface 121 of the primer resin layer 120 to which the roughness is transferred is used to form circuit patterns.

The roughness and shape of the ribs 113 are not be limited to a particular roughness and shape, so long as the roughness and shape are sufficient to form the corresponding ribs 123 on the first surface 121 of the primer resin layer 120 and provide the adhesion between the circuit pattern 172, to be formed on the upper part of the primer resin layer 120, and the primer resin layer 120. For example, the roughness of the ribs 113 may be about 0.05 to about 0.4 μm in height.

According to one example, a thickness of the copper foil layer 110 may be about 0.2 μm to about 3.0 μm. When the thickness of the copper foil layer 110 is less than about 0.2 μm, it may be difficult to form the copper foil layer 110 having uniform thickness and ribs. On the other hand, when the thickness of the copper foil layer 110 is greater than about 3.0 μm, it may be difficult to form vias and circuits through laser irradiation.

The carrier film 140 is disposed on the first surface 111 of the copper foil layer 110. The carrier film 140 supports the copper foil layer 110 to facilitate handling. The carrier film 140 may be formed of a metal such as Cu and All or a resin such as a polyimide, an epoxy, a phenol, a polyphenylene ether, and a polyphenylene oxide. However, the material for forming the carrier film 140 is not limited to such examples. A thickness of the carrier film 140 is not limited to specific values. For example, the thickness may be enough to support the copper foil layer 110 and perform other processes.

When the copper foil layer 110 is eliminated, the ribs 113 are exposed to the outside environment. When the conductive circuit pattern 172 is formed on the first surface 121 of the primer resin layer 120 on which the ribs 123 are formed, adhesion is thereby improved between the circuit pattern 172 and the primer resin layer 120.

The primer resin layer 120 may include, for example, at least one of an epoxy resin, a polyimide resin, a polyamide-imide resin, a polyamide resin, a liquid crystal polymer resin, and a cycloolefin resin.

The primer resin layer 120 may further include a filler to increase physical properties. The filler may include, for example, at least one of a metal oxide filler and an organic filler in an amount greater than 0 wt % and less than about 10 wt % , excluding. However, filler is not limited to these specific examples.

The build-up resin layer 130 is formed below the primer resin layer 120 on a second, lower surface 122 of the primer resin layer 120 and functions as an insulating layer in the printed circuit board 200 (FIG. 2F) to be formed using the resin-coated copper foil 100.

A via metal 171 (FIG. 2E) is formed in the build-up resin layer 130 and the circuit pattern 172 is formed on the first surface 121 of the primer resin layer 120, which is formed on the upper part of the build-up resin layer 130, to provide the printed circuit board 200.

The build-up resin layer 130 may include at least one of an epoxy resin, a butyral resin, and a polyamide-imide resin. The build-up resin layer 130 may further include a metal oxide filler or an organic filler. A kind and an amount of the filler included in the build-up resin layer 130 may be controlled as necessary. For example, when a silica filler having a particle size of about 0.2 pm to about 0.5 μm is used in an amount of about 40 wt % to about 80 wt %, it may reduce warpage issues of the printed circuit board.

### Method of Manufacturing a Printed Circuit Board

Hereinafter, a method of manufacturing a printed circuit board 200 using a first (upper) resin-coated copper foil 100 and a second (lower) resin-coated copper foil 100 will be described with reference to FIGS. 2A to 2F. Since the structure of the resin-coated copper foils 100 is described above with respect to FIG. 1, redundant explanations of the structure are omitted below.

FIGS. 2A and 2B illustrate examples of first (upper) and second (lower) resin coated copper foils 100 before and after laminate molding of the resin-coated copper foils 100. In the laminate molding, the first and second resin-coated copper foils 100 are laminated on an upper surface and a lower surface, respectively, of a center circuit part 150 in which an electronic component is mounted or circuits are formed.

Referring to FIG. 2A, for each resin-coated copper foil 100 that is to be formed, a carrier film 140 and a copper foil layer 110 including a first surface 111 and a second surface 112 are prepared. One surface of the carrier film 140 is release-treated. A laser absorptance of the first surface 111 of the copper foil layer 110 is greater than a laser absorptance of the second surface 112 of the copper foil layer 110.

The term ‘release-treatment’ refers to a chemical conversion treatment which may be performed to easily eliminate the carrier film 140 from the copper foil layer 110, for example, a fluorine plating treatment.

The first surface 111 of the copper foil layer 110 is faced to the one surface of the carrier film 140, which is release-treated. The ribs 113 are formed on the second surface 112 of the copper foil layer 110.

The forming of the ribs 113 on the second surface 112 of the copper foil layer 110 includes, for example, forming Cu nodules on the second surface 112 of the copper foil layer 110. A shape and size of the ribs 113 may be controlled based on a shape, size, and content of the nodules.

The primer resin layer 120 is formed on the second surface 112 of the copper foil layer 110, on which the ribs 113 are formed. The ribs 113 interface with a first surface 121 of the primer resin layer 120 which is in contact with the second surface 112 of the copper foil layer 110.

A method of forming the primer resin layer 120 may not be particularly limited. For example, the primer resin layer 120 may be formed by coating a varnish including at least one of an epoxy resin, a polyimide resin, a polyamide-imide resin, a polyamide resin, a liquid crystal polymer resin, and a cycloolefin resin on the second surface 112 of the copper foil layer 110, on which the ribs 113 are formed, and curing the result. The primer resin layer 120 may have a cure degree of about 90% or above. The ribs 113 cause the ribs 123, which interface with the ribs 113, to form on the first surface 121 of the primer resin layer 120.

The build-up resin layer 130 is formed on the second surface 122 of the primer resin layer 120 to form the resin-coated copper foil 100.

A method of forming the build-up resin layer 130 may not be particularly limited. For example, the build-up resin layer 130 may be formed by coating a varnish including at least one of an epoxy resin, a butyral resin, and a polyamide-imide resin on the primer resin layer 120 and drying the result at a temperature between about 50° C. and about 110° C. into a b-state. When the drying temperature is higher than about 110° C., it may not be used as a build-up material due to curing of the resin.

Referring to FIG. 2B, the respective build-up resin layers 130 are adhered to the upper and lower surfaces of the center circuit part 150 and the carrier films 140 are exposed to the outside. While FIGS. 2A and 2B illustrate the first and second resin-coated copper foils 100 on the upper and lower surfaces, respectively, of the center circuit part 150, a resin-coated copper foil 100 may be formed only on one surface of the center circuit part 150.

Referring to FIG. 2C, in the first and second resin-coated copper foils 100, the carrier film 140 is eliminated, and a circuit of the center circuit part 150 is exposed and a via 160 is formed by irradiating laser light on the first surface 111 of the copper foil layer 110. When the carrier film 140 is eliminated, the first surface 111 of the copper foil layer 110 is exposed to the outside environment. The via 160 is formed and the circuit of the center circuit part 150 is exposed by irradiating laser light on the exposed first surface 111 of the copper foil layer 110. A kind of laser used may not be particularly limited. For example, the laser may be a CO2 laser. The first surface 111 of the copper foil layer 110 is surface-treated to facilitate laser processing so that the laser processing may be performed even though the copper foil layer 110 is formed on the primer resin layer 120.

Referring to FIG. 2D, if needed, the copper foil layer 110 is eliminated. A method of eliminating the copper foil layer 110 may not be particularly limited. For example, the copper foil layer 110 may be eliminated through an etching process. The etching process may eliminate only the copper foil layer 110 by using an etching material having a high etch selectivity for the copper foil layer 110 and the primer resin layer 120 formed to the inside of the copper foil layer 110. When the copper foil layer 110 is eliminated, the first surface 121 of the primer resin layer 120, on which the ribs 123 are formed, is exposed to the outside environment.

Referring to FIG. 2E, a via metal 171 and a circuit pattern 172 are formed by filling the via 160 with a conductive material. The via metal 171 and the circuit pattern 172 are formed through a lithography process. For example, the via metal 171 and the circuit pattern 172 may be formed by coating the outside part of the primer resin layer 120 with a photoresist material, exposing and developing the resulting coating, forming a seed layer at the portion where the circuit pattern 172 is to be formed and forming the via metal 171 and the circuit pattern 172 from the seed layer using a plating process. Thus, the circuit pattern 172 is formed to interface with the ribs 123, thereby increasing adhesion between the primer resin layer 120 and the circuit patter 172.

Referring to FIG. 2F, if needed, another laminate in which a carrier film 140, a copper foil layer 110, a primer resin layer 120 and a build-up resin layer 130 are laminated is laminated on the primer resin layer 120 on which the circuit pattern 172 is formed. As shown in FIG. 2F, an outer insulating layer 180 is formed at the outmost part and the via 160 and the circuit is formed. A bump 190 is formed on a portion of the circuit pattern 172 to provide the multi-layered printed circuit board 200.

When the printed circuit board 200 is formed by using the primer resin layer 120 on which the ribs 123 are formed by the copper foil layer 110, forming a prepreg may be eliminated and a curing process for forming the prepreg may be further eliminated, in comparison to a general process of forming grooves on the surface of a prepreg and embedding fine patterns to adhere to the build-up resin layer 130. Accordingly, the overall manufacturing process is simplified, a defect rate from the manufacturing process is lowered and a manufacturing cost is further reduced. Since the ribs 123 are formed on the primer resin layer 120, adhesion between the primer resin layer 120 and the circuit pattern 172 is increased to reduce the defect rate. Forming the printed circuit board 200 as described also allows the use of various kinds of fillers in the primer resin layer 120 and the build-up resin layer 130.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A resin-coated copper foil, comprising:
a copper foil layer comprising a first surface and a second surface, wherein a laser absorptance of the first surface of the copper foil layer is greater than a laser absorptance of the second surface of the copper foil layer, and wherein ribs are formed on the second surface of the copper foil layer;
a carrier film disposed on the first surface of the copper foil layer;
a primer resin layer disposed on the second surface of the copper foil layer; and
a build-up resin layer disposed on the primer resin layer.

2. The resin-coated copper foil of claim 1, wherein the first surface of the copper foil layer is surface-treated with at least one selected from the group consisting of Ni, Co and Zn.

3. The resin-coated copper foil of claim 1, wherein a thickness of the copper foil layer is about 0.2 μm to about 3.0 μm.

4. The resin-coated copper foil of claim 1, wherein the primer resin layer comprises at least one selected from the group consisting of an epoxy resin, a polyimide resin, a polyamide-imide resin, a polyamide resin, a liquid crystal polymer resin, and a cycloolefin resin.

5. The resin-coated copper foil of claim 1, wherein the primer resin layer comprises at least one of a metal oxide filler and an organic filler in an amount greater than 0 wt % and less than about 10 wt %.

6. The resin-coated copper foil of claim 1, wherein the build-up resin layer comprises at least one selected from the group consisting of an epoxy resin, a butyral resin, and a polyamide-imide resin.

7. The resin-coated copper foil of claim 1, wherein the build-up resin layer comprises at least one of a metal oxide filler and an organic filler in an amount of about 40 wt % to about 80 wt %.

8. The resin-coated copper foil of claim 1, wherein the primer resin layer has a cure degree of about 90% or above.

9. The resin-coated copper foil of claim 1, wherein the build-up resin layer is in a b-stage.

10. The resin-coated copper foil of claim 1, wherein the primer resin layer comprises ribs interfacing with the ribs on the second surface of the copper foil layer.

11. The resin-coated copper foil of claim 1, wherein the ribs on the second surface of the copper foil layer are uniform in size and shape.

12. A method of manufacturing a printed circuit board comprising:
preparing a carrier film comprising a release-treated surface;
forming a copper foil layer comprising a first surface and a second surface, wherein the first surface of the copper foil layer faces the release-treated surface of the carrier film, and wherein a laser absorptance of the first surface of the copper foil layer is greater than a laser absorptance of the second surface of the copper foil layer;
forming ribs on the second surface of the copper foil layer;
forming a primer resin layer on the second surface of the copper foil layer after forming the ribs;
forming a build-up resin layer on the primer resin layer to provide a resin-coated copper foil;
laminate molding the resin-coated copper foil to face a surface of a center circuit part with the build-up resin layer;
exposing a circuit of the center circuit part and forming a via by eliminating the carrier film and irradiating laser light on the first surface of the copper foil layer; and
forming a circuit pattern by filling the via with a conductive material.

13. The method of claim 12, wherein the preparing of the copper foil layer comprises surface-treating the first surface of the copper foil layer with at least one selected from the group consisting of Ni, Co, and Zn.

14. The method of claim 12, further comprising eliminating the copper foil layer after the forming of the circuit and the via, and prior to the forming of the circuit pattern.

15. The method of claim 12, wherein a thickness of the copper foil layer is about 0.2 μm to about 3.0 μm.

16. The method of claim 12, wherein the forming of the primer resin layer comprises forming ribs on the primer resin layer that interface with the ribs on the second surface of the copper foil layer.

17. The method of claim 16, wherein the forming of the circuit pattern comprises forming the circuit pattern to interface with the ribs on the primer resin layer.
